(19) United States
(12) Patent Application Publication
(10) Pub. No.: US 2010/0117667 A1
(43) Pub. Date: May 13, 2010

(54) Method and means for optical detection of internal-node signals in an integrated circuit device

(76) Inventor: William K. Lo, San Jose, CA (US)

Correspondence Address: DAVID LEWIS, 1250 AVIATION AVE., SUITE 200B, SAN JOSE, CA, 95110, US

(21) Appl. No.: 12/590,507

(22) Filed: Nov. 9, 2009

Related U.S. Application Data
(60) Provisional application No. 61/198,547, filed on Nov. 7, 2008.

(51) Int. Cl. G01R 31/02

(52) U.S. Cl. 324/754

(57) ABSTRACT

A continuous-wave laser beam is chopped to form pulses synchronized to the activity of a device under testing and/or to acquisition electronics. Chopping the laser beam to reduce the duty-cycle of the beam allows the power delivered to the device during the actual probing time interval to be increased while maintaining a lower average power. Chopping the laser beam improves the signal-to-noise ratio of the continuous-wave laser voltage probing measurements. Chopping the laser beam improves the performance of the continuous-wave laser based laser voltage probing system, which may be used for measuring the internal signals of an operating integrated circuit device.

### CROSS-REFERENCE TO RELATED APPLICATIONS

This application claims priority benefit of U.S. Provisional Patent Application No. 61/198,547 (Docket # 84-1), entitled “METHOD AND MEANS FOR IMPROVED OPTICAL DETECTION OF INTERNAL-NODE SIGNALS IN AN INTEGRATED CIRCUIT DEVICE,” filed Nov. 7, 2008, by William K. Lo, which is incorporated herein by reference.

### FIELD

The present invention relates to methods and apparatus for probing of an IC (integrated circuit) device with a CW (continuous-wave) light source.

### BACKGROUND

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches, which in and of themselves may also be inventions.

Laser Voltage Probing (LVP) is an established technique used to extract signals from the internal circuitry of operating silicon integrated circuit (IC) devices for the purposes of design debug, failure analysis, or other diagnostic activities. The technique dates back to the mid-1980's with the pioneering work of Heinrich and Bloom (U.S. Pat. No. 4,758,092, July 1988, Method and means for optical detection of charge density modulation in a semiconductor) but was not widely used until the late 1990s when the first commercial system, the Schlumberger IDS2000, became available.

The Schlumberger IDS2000 used pulses from a mode-locked laser source and used custom data acquisition electronics to make measurements via stroboscopic sampling (also referred to as equivalent-time-sampling). A noise cancellation technique was invented for the IDS2000 to reduce the effect of noise caused by DUT vibrations (U.S. Pat. No. 5,905,577, May 1999, Dual-laser voltage probing of IC's).

As demonstrated by Heinrich, Bloom, and Hemenway (Applied Physics Letters 48(16), 1986, pp 1066-8, Noninvasive sheet charge density probe for integrated silicon devices) LVP can also be performed using a CW (continuous-wave) laser with a real-time oscilloscope for the acquisition electronics. Modern real-time digital storage oscilloscopes use fast analog-to-digital converters to digitize the data. They acquire the waveform data as a series of samples. For the same average laser power, the number of photons captured in each sampling interval in a CW laser based LVP system is much less than the number of photons in a single pulse from the mode-locked laser in a stroboscopic sampling based LVP system. This relative photon deficit increases the photon shot noise, so it is detrimental to the signal-to-noise ratio of the measurements made by the CW laser based LVP system.

In principle, it is possible to increase CW laser power to make up for the photon deficit. In practice, however, there is a limit to the amount of laser power that can be delivered to the DUT before the device is damaged and/or other invasive effects occur. For CW lasers, the primary damage mechanism is thought to be thermal (heating) in nature which is related to the average laser power delivered. Therefore, there is a practical upper limit to how much average CW power can be used during a measurement.

### SUMMARY

Although various embodiments of the invention may have been motivated by various deficiencies with the prior art, which may be discussed or alluded to in one or more places in the specification, the embodiments of the invention do not necessarily address any of these deficiencies. In other words, different embodiments of the invention may address different deficiencies that may be discussed in the specification. Some embodiments may only partially address some deficiencies or just one deficiency that may be discussed in the specification, and some embodiments may not address any of these deficiencies.

In an embodiment, a continuous-wave laser beam is chopped to form pulses synchronized to the activity of interest of a device under testing (DUT). In another embodiment, a continuous-wave laser beam is chopped to form pulses synchronized to the measurement activity of the acquisition electronics. By chopping the laser beam the duty-cycle of the beam is reduced, which allows the power delivered to the device during the actual measurement time interval to be increased while maintaining a lower average power. By chopping the laser beam the signal-to-noise ratio (SNR) is improved during the continuous-wave laser voltage probing measurements. By chopping the laser beam the performance of the continuous-wave laser based laser voltage probing system is improved, thereby improving the measuring of the internal signals of an operating integrated circuit device.

In an embodiment, the DUT is a complex IC exercised with a test pattern that generates an electrical response in at least part of the internal circuitry of the IC. Various methods for applying the test pattern can be used. For example, the test pattern may be a functional test pattern applied to the input connections of the packaged IC by an automatic test equipment (ATE) tester, or the test pattern may be generated by built-in self-test (BIST) circuitry in the IC, activated by applying signals to the IC through a Joint Test Action Group (JTAG) interface, or the test pattern may be one or more software applications running on a computer, exercising the IC in a system-level environment representative of its intended application. There are many other methods of applying test patterns. To improve SNR, LVP measurement data is accumulated and/or averaged multiple times, requiring at least the signal(s) of interest inside the IC be made repetitive. To generate a repetitive signal(s) of interest, the test pattern itself may be caused to be repetitive, or portions within the test pattern corresponding to the signal(s) of interest may be caused to be repetitive, or other means may be used.

In an embodiment, the chosen test pattern is such that the signal(s) of interest only span a fraction of the total test pattern period. In an embodiment, the signal(s) of interest indicates whether or not a portion or a function of interest of the IC is behaving properly. In another embodiment, the signal(s) of interest may indicate if a component attached to the IC is behaving properly. In another embodiment, the IC may be probed to facilitate determining whether the test pattern or other input signals are correct. It may be that the entire test pattern is necessary to produce the signal(s) of interest, or it may be that only a portion of the test pattern is necessary to produce the signal(s) of interest. However, although the rest of the DUT's response to the test pattern may contain information, the rest of the response is not necessary for determining whether the portion or function of interest of the IC is behaving properly. The IC operation is only analyzed over a portion of the total response of the IC to the test pattern. Instead of illuminating the DUT with laser radiation over the total test pattern period, the CW laser beam is chopped to form pulses that are synchronized with, the signal(s) of interest. The total average laser radiation delivered to the DUT is then significantly reduced and/or the power or intensity of the laser radiation during the actual measurement time span is increased. The total test pattern may span 100 microseconds, for example, while the signal(s) of interest may span only 100 ns. In this case, irradiating the DUT only during the span of the signal(s) of interest instead of the whole test pattern allows the average laser power incident on the DUT to be reduced by 1000 times. Alternatively, the power applied during the measurements may be increased by 1000 times while maintaining the same average power (although, in practice, it may be necessary to limit the actual increase in power to a more modest level).

In an embodiment, the signal(s) of interest span the whole test pattern period. In this case, synchronizing the laser pulses to the signal(s) of interest requires that the laser irradiate the DUT continuously, and so no advantage is gained over an unchopped CW-LVP measurement. However, due, for example, to inefficiencies in the acquisition electronics used to measure the signal(s) of interest, not all repetitions of the signal(s) of interest may be measured. For example, dead-time of the acquisition electronics may prevent the making of measurements on a subsequent repetition of the signal(s) of interest if the repetition follows soon after a previous measurement. In an embodiment, the laser pulses are synchronized with the measurement activity of the acquisition electronics instead of more directly to the signal(s) of interest. In this way, laser pulses are only generated when the acquisition electronics is capable of making measurements. Dead time, may, for example, only allow every fourth repetition of the signal(s) of interest to be acquired. Irradiating the DUT only during those repetitions when the acquisition electronics is capable of making a measurement then reduces the average laser power delivered to the DUT by four times. Alternatively, the peak laser power used during the measurements can be increased by up to four times.

In another embodiment, the signal(s) of interest may repetitively occur at indeterminate times within the test pattern. For example, when testing signals related to memory read operations in a DUT in a systems-level test environment, the memory read operations may be the same each time for a particular memory element, but the read operation may be performed at indeterminate times within the test pattern. Some instances of the signal(s) of interest may occur close in time to other instances, while some instances may be spaced much further apart in time. In this situation, synchronizing the laser pulses to the measurement activity of the acquisition electronics also provides benefits, by allowing less average laser power to be used for probing, for example.

In an embodiment, the laser radiation during the measurement time span is increased over what the radiation would have been had the laser radiation been applied during the entire test pattern or during the entire time of test. Increasing the radiation reduces the impact of shot noise thereby improving the measurement SNR, allowing acquisition times to be reduced by reducing the number of times that the same measurement needs to be taken to obtain a final waveform image with sufficiently high SNR and/or, allowing a final waveform with higher SNR to be obtained in the same amount of time (or a combination both). Optionally, transient effects of the laser beam on the reflected laser beam may be compensated for. Some examples of transient effects are thermal effects and the creation of free carriers, such as electron hole pairs, which may affect the index of refraction and/or the absorption of light by the silicon.

It is not necessary to reduce the laser beam to zero intensity during the ‘off’ periods. However, the effectiveness of this scheme may be reduced, depending on how much laser radiation ‘leaks’ through to the DUT during the ‘off’ periods.

Any of the above embodiments may be used alone or together with one another in any combination. Inventions encompassed within this specification may also include embodiments that are only partially mentioned or alluded to or are not mentioned or alluded to at all in this brief summary or in the abstract.

### BRIEF DESCRIPTION OF THE FIGURES

In the following drawings like reference numbers are used to refer to like elements. Although the following figures depict various examples of the invention, the invention is not limited to the examples depicted in the figures.

FIG. 1 shows a schematic illustration of the basic components of a Laser Voltage Probing (LVP) system.

FIG. 2A shows a block diagram of an embodiment of a Laser Source used in Laser Voltage Probing system of FIG. 1.

FIG. 2B shows a block diagram of an embodiment of Acquisition Electronics used in Laser Voltage Probing system of FIG. 1.

FIG. 2C shows a block diagram of an embodiment of a Acquisition Electronics used in Laser Voltage Probing system of FIG. 1.

FIG. 2D shows a block diagram of an embodiment of a DUT Stimulus used in the Laser Voltage Probing system of FIG. 1.

FIG. 2E shows a block diagram of an embodiment of a DUT Stimulus used in the Laser Voltage Probing system of FIG. 1.

FIG. 2F shows a block diagram of an embodiment of a Photodetector used in the Laser Voltage Probing system of FIG. 1.

FIG. 2G shows a block diagram of an embodiment of a Photodetector used in the Laser Voltage Probing system of FIG. 1.

FIG. 2H shows a block diagram of an embodiment of a Microscope Optics used in Laser Voltage Probing system of FIG. 1.

FIG. 2I shows a block diagram of an embodiment of a workstation used in Laser Voltage Probing system of FIG. 1.

FIG. 2J shows a diagram of an embodiment of a DUT being irradiated with a laser beam.

FIG. 3 shows timing diagram of an embodiment of Laser Voltage Probing with Chopped CW Laser and with Real-Time Sampling.

FIG. 4A shows a plot illustrating an example of the temperature response of the DUT to an application of laser light.

FIG. 4B shows a plot illustrating the temperature response to the chopped continuous wave laser signal.

FIG. 5A shows a flowchart of an embodiment of a method of setting up the system of FIG. 1 for waveform acquisition.

FIG. 5B shows a flowchart of an embodiment of a method of using the system of FIG. 1

FIG. 6 is a flowchart of an embodiment of a method of making the system of FIG. 1.

FIG. 7A is a flowchart of an embodiment of a method of determining the damage threshold of a DUT irradiated with a CW laser beam.

FIG. 7B is a flowchart of an embodiment of a method of determining the damage threshold of a DUT irradiated with a chopped CW laser beam.

### DETAILED DESCRIPTION

Although various embodiments of the invention may have been motivated by various deficiencies with the prior art, which may be discussed or alluded to in one or more places in the specification, the embodiments of the invention do not necessarily address any of these deficiencies. In other words, different embodiments of the invention may address different deficiencies that may be discussed in the specification. Some embodiments may only partially address some deficiencies or just one deficiency that may be discussed in the specification, and some embodiments may not address any of these deficiencies. In the specification, the terms irradiate and illuminate and their conjugations may be substituted one for the other to obtain different embodiments.

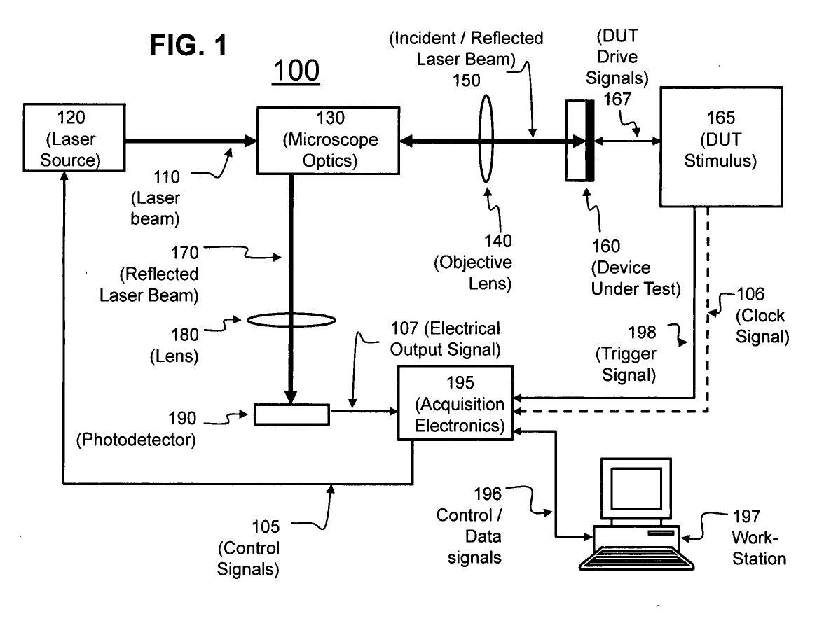

In general, at the beginning of the discussion of each of FIGS. 1-4B is a brief description of each element, which may have no more than the name of each of the elements in the one of FIGS. 1-4B that is being discussed. The brief description is usually given in numerical order to facilitate easily locating a particular element. After the brief description of each element, each element is further discussed. Nonetheless, there is no one location where all of the information of any element of FIGS. 1-7B is necessarily located. Unique information about any particular element or any other aspect of any of FIGS. 1-7B may be found in, or implied by, any part of the specification.

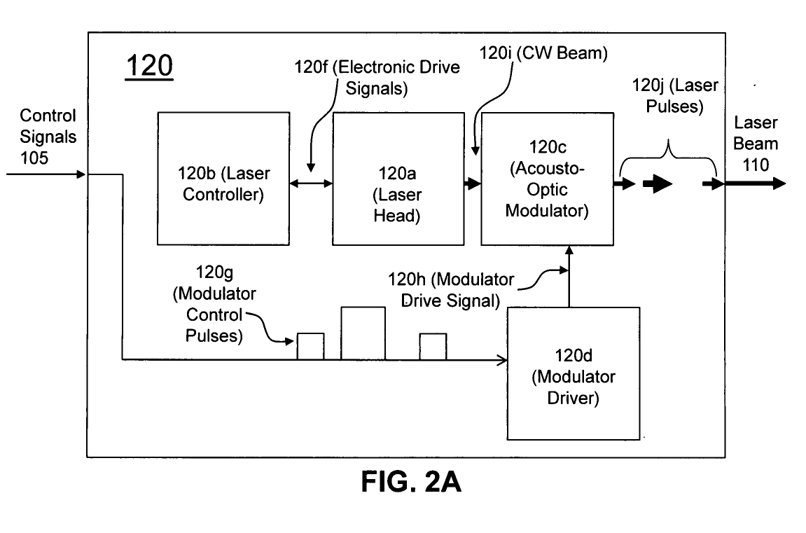

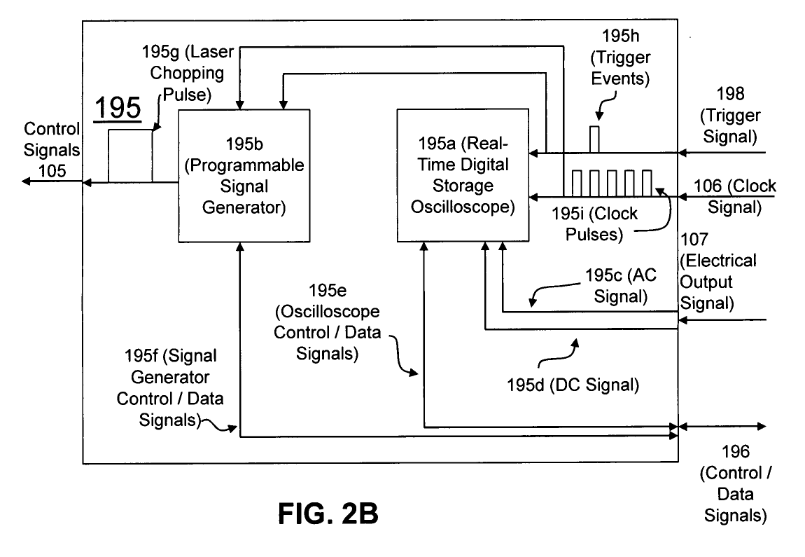

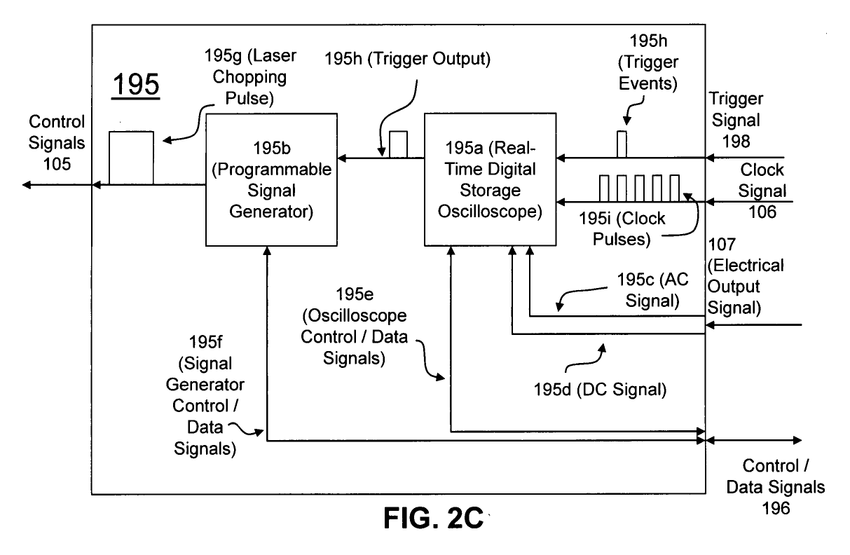

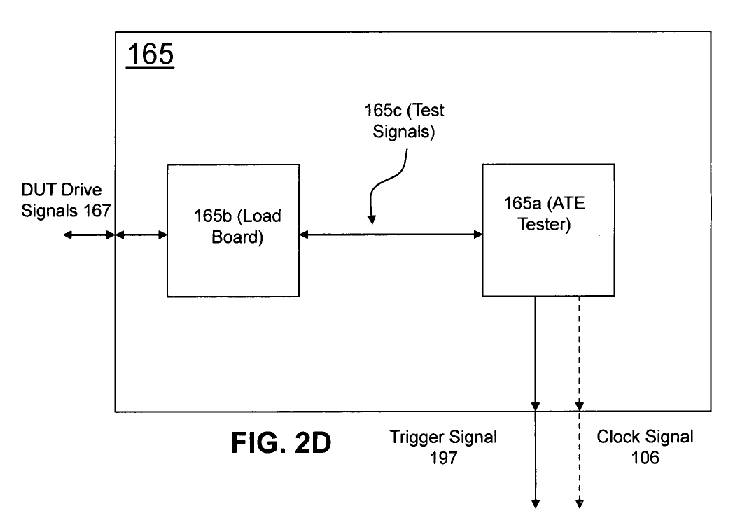

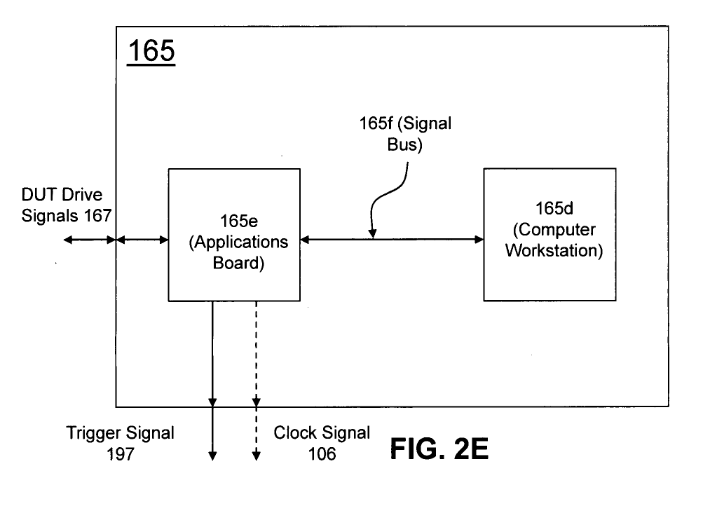

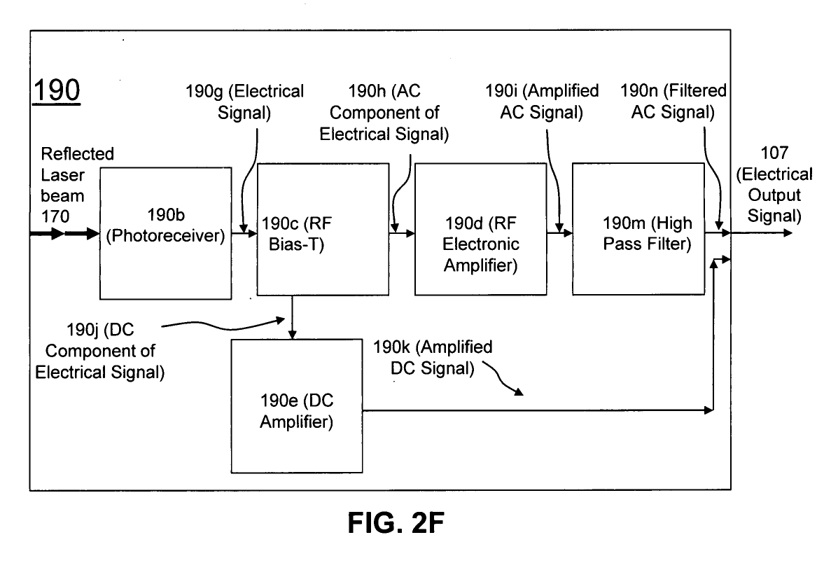

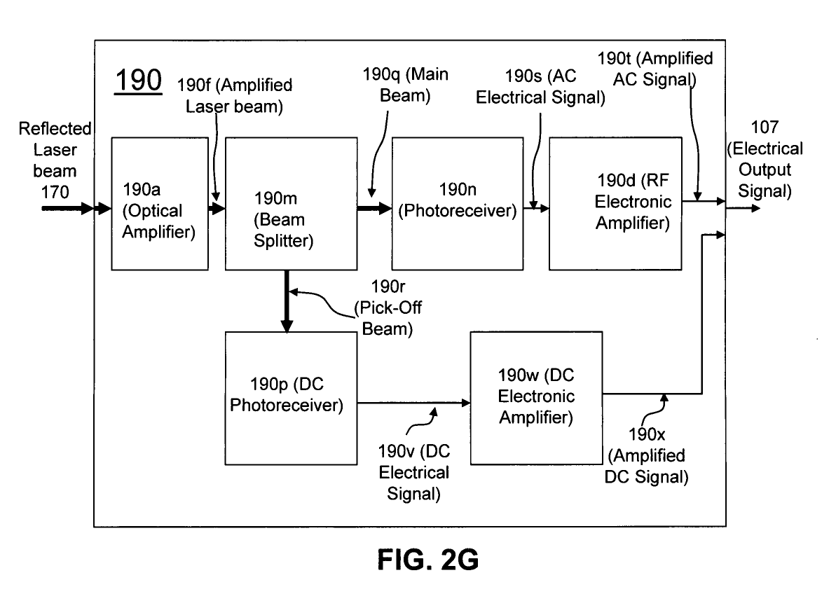

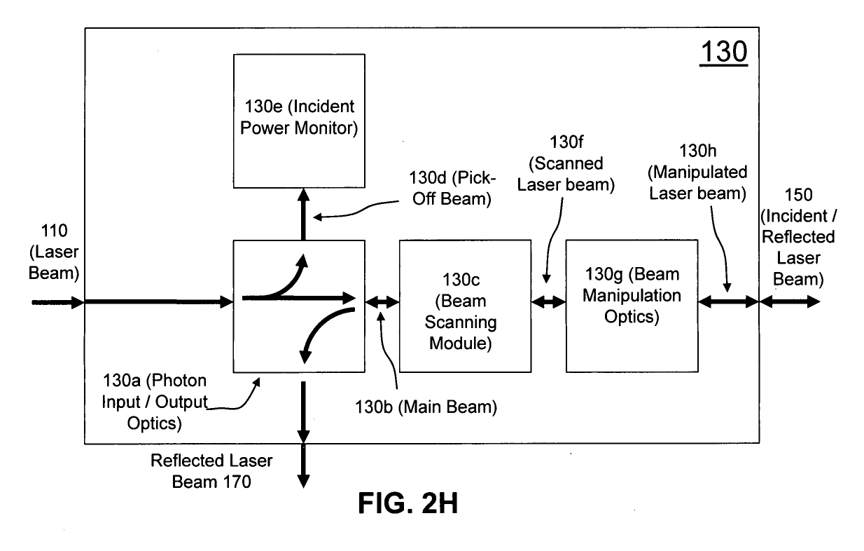

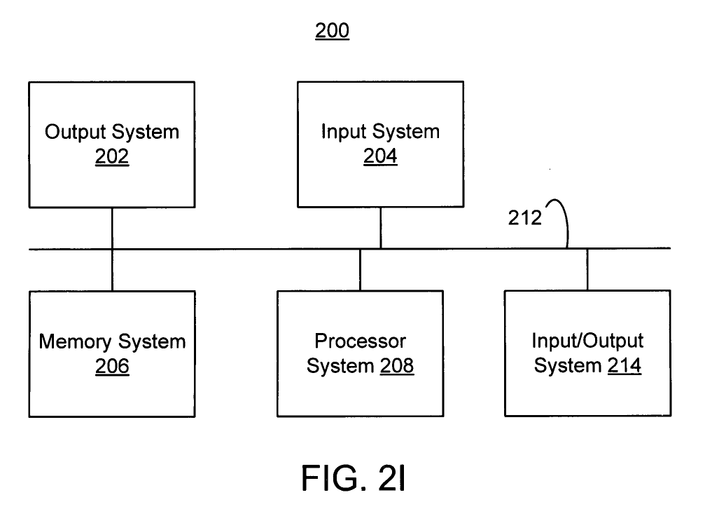

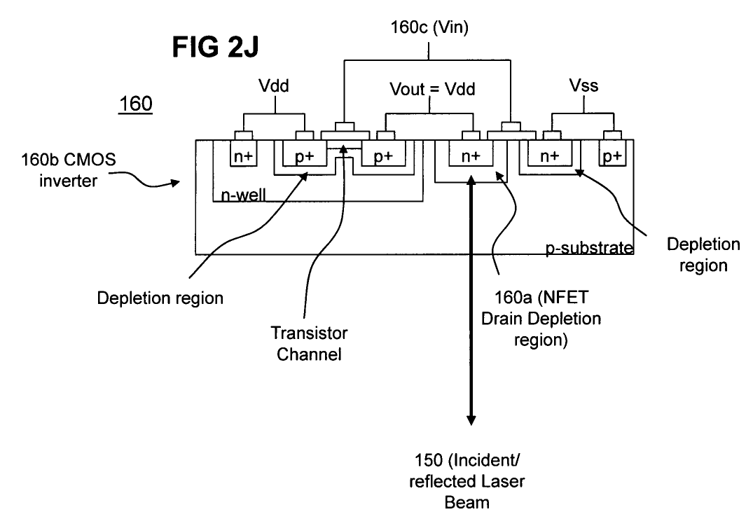

In general, heavy weight lines in FIG. 1 and FIG. 2 are used to represent laser radiation paths while lighter weight lines are used to represent electrical signal paths. While electrical paths may be drawn as a single line, this is done for the purposes of clarity only and it is to be understood that these paths may represent multiple signals and multiple physical wires may be used to carry these signals. While laser radiation is generally shown as traversing ‘free-space’ for the purposes of clarity, it is understood that fiber optic cables may be used for beam delivery, where convenient and appropriate, and that using fiber optic cables may also entail the use of fiber coupling and/or fiber collimating optics.

For the sake of clarity, components that are not necessary for an understanding of the invention (but that would be understood to be present by one of ordinary skill in the art) are not shown. These include, but are not limited to, components such as a objective lens turret to allow different microscope imaging fields-of-view and different focused laser spot sizes, mechanical stages to allow navigation of the optical components relative to the DUT, Control signals for the microscope optics to allow the laser beam to be raster scanned for imaging and statically pointed at a specific location for laser voltage probing, cooling apparatus to temperature control the DUT, and power supplies to provide power to the various components.

FIG. 1 shows a schematic illustration of the basic components of an embodiment of Laser Voltage Probing (LVP) system 100. In other embodiments LVP system 100 may not have all of the elements or features listed and/or may have other elements or features instead of or in addition to those listed.

FIG. 1 includes laser source control signals 105, clock signal 106, photodetector electrical output signal 107, laser radiation 110, laser source 120, microscope optics 130, and objective lens 140, and incident/reflected laser beam 150, Device Under Test (DUT) 160, device stimulus 165, device drive and response signals 167, reflected laser beam 170, photodetector focusing lens 180, photodetector 190, acquisition electronics 195, control and data signals 196, computer workstation 197, and trigger signal 198.

A beam of NIR (near-infrared) laser radiation 110 from a laser source 120, which is generated under the control of control signals 105, are focused into the DUT 160 using microscope optics 130 and objective lens 140. During laser voltage probing, laser radiation 110 is a chopped continuous wave laser beam. The portion of the laser radiation reflected by the DUT and re-collected by the objective lens retraces the beam path into microscope optics 130 which diverts it to lens 180 which then focuses it into photodetector 190. Output signal 107 from photodetector 190 is digitized using acquisition electronics 195. Acquired waveform data is transferred through data signals 196 to workstation 197 for further processing, display, and storage.

Control signals 105 are generated by the acquisition electronics 195 to control the laser source. Laser source 120 incorporates one or more sources of laser radiation that allows generating a continuous output and an optionally chopped output to form pulses of laser radiation for laser voltage probing. Control signals 105 and laser source 120 are further discussed, below, and in the context of FIG. 2A and FIG. 2B.

Trigger signal 198 is a signal used to synchronize the laser radiation irradiating the DUT and/or to synchronize the acquisition electronics with the DUT signal(s) of interest. Trigger signal 198 is generated by the electronics that stimulates the DUT, or is, alternately, generated by the DUT and is routed through the electronics for the purposes of signal buffering and/or for convenience. Clock signal 106 is a clock signal generated by the electronics that stimulates the DUT, or is, alternately, a clock signal generated by the DUT that is routed through the electronics for the purposes of signal buffering and/or for convenience. The clock signal 106 may be used to aid in the synchronization of the laser radiation irradiating the DUT and/or to aid in the synchronization of the acquisition electronics with the DUT signal(s) of interest. Clock signal 106, trigger signal 198, and DUT stimulus 165 are discussed further, below, and with reference to FIG. 2B, FIG. 2C, FIG. 2D, and FIG. 2E.

Electrical output signal 107 is the electrical representation of reflected laser beam signal 170 after conversion by the photodetector. Conversion of the laser signal 170 to electrical signal 107 allows the signal to be processed by the acquisition electronics 195. The conversion process may involve filtering the signal and/or involve splitting the signal into multiple signals for separate acquisition. Splitting the signal may occur optically and/or electrically. The photodetector 190, the electrical output signal 107, and the laser signal 170 are discussed further, below, with reference to FIG. 2F, FIG. 2G and FIG. 2H.

Acquisition electronics 195 contains electronics that digitizes the photodetector output signal 107. Prior to and after digitization, further processing of the output signal 107 may occur. Prior to digitization, amplification, attenuation, and/or offsetting of the signal may be necessary to match the signal level to the input range of the analog-to-digital converter (ADC), and bandwidth limiting filters may be applied, for example. After digitization, digital filtering, averaging, binning of the data, for example, may be performed. Acquisition electronics is further discussed below, and with reference to FIG. 2B and FIG. 2C.

Computer workstation 197 runs the software which controls the laser voltage probing system and/or further processes, displays, and stores the waveform data. Waveform data is transferred from acquisition electronics 185 through data signals 196 to workstation 197. Computer workstation 197 is further discussed below, with reference to FIG. 2I.

The microscope optics 130 includes optics that is useful for directing laser beam 110 to objective lens 140 in a manner such that objective lens 140 can direct a focused laser spot into DUT 160 for the purposes of imaging and/or for the purposes of laser voltage probing. Microscope optics 130 also contains the optics required to separate the portion of laser beam 150 reflected by the DUT from the portion of laser beam 150 focused into the DUT and from laser beam 110 delivered to microscope optics 130 from laser source 120. Microscope optics 130 is further discussed below with reference to FIG. 2H.

FIG. 2A shows a block diagram of an embodiment of the components in a laser source 120. Laser source 120 includes laser head 120a, laser controller 120b, beam modulator 120c, modulator driver 120d, laser drive signal 120f, modulator control pulses 120g, and modulator drive signal 120h. Laser head 120a generates CW laser beam 120i which is chopped to form pulses 120j by modulator 120c under control of modulator driver 120d and modulator control pulses 120g. In other embodiments laser source 120 may not have all of the elements or features listed and/or may have other elements or features instead of or in addition to those listed.

Modulator control pulses 120g are generated by acquisition electronics 195 and transferred to laser source 120 through control signals 105. In an embodiment, modulator driver 120d is an analog driver that can be used to generate laser pulses of variable amplitude, and/or of complex shape, according to the amplitude and shape of the modulator control pulses 120g.

The laser, including laser head 120a and laser controller 120b, is used as a component of laser source 120 to generate CW beam 120i. Any of several types of laser sources may be used for laser source 120, including laser diodes, diode-pumped solid-state lasers, fiber lasers, q-switched lasers, etc.

Although FIG. 2A shows an Acousto-optic modulator 120c being used to chop the CW laser beam 120i, chopping a laser beam can be accomplished by a variety of other means: Mechanical, electro-optical, pulsing of the laser drive current, beam deflection (such as occurs in a laser scanning microscope (LSM)) across an aperture, q-switching of the laser, and other means that will be apparent to those skilled in the art. Electro-optical modulators, acousto-optical modulators, and drive-current pulsing can allow some level of pulse shaping (versus simply turning the laser on and/or off). Shaping of the laser pulse may be advantageous, for example, to limit the size of the impulse delivered to the photoreceiver and electronics by purposely degrading the on/off and off/on transition times. The use of electro-optical modulators, acousto-optical modulators, and drive-current pulsing also allow CW laser pulse-widths, duty-cycles, and pulse shapes to be easily and widely varied. The use of electro-optical modulators, acousto-optical modulators, and drive-current pulsing also allow the laser beam to be variably attenuated for laser power control.

Although FIG. 2A shows only one laser in laser source 120, multiple lasers can be used to generate multiple beams 110. A laser primarily intended for laser voltage probing can be combined with a laser primarily intended for laser scanning microscope (LSM) imaging, for example. In one embodiment, the laser intended for LSM imaging can be a broadband source with wide spectrum for reducing the effects of interference, while the laser intended for LVP can be narrowband with narrow spectrum designed especially to have low laser noise.

FIG. 2B shows a block diagram of an embodiment of the components in acquisition electronics 195. Acquisition electronics 195 includes oscilloscope 195a and signal generator 195b. In other embodiments, acquisition electronics 195 may not have all of the elements or features listed and/or may have other elements or features instead of or in addition to those listed.

Two input channels of oscilloscope 195a are used to acquire AC signal 195c and DC signal 195d, which are generated by photodetector 190 and transferred to acquisition electronics through output signal 107. The acquisition of data by oscilloscope 195a is synchronized to the DUT signal(s) of interest using trigger events 195h and optionally with the aid of clock pulses 195i, both of which are from DUT stimulus 165 and transferred to acquisition electronics through trigger signal path 198 and clock signal path 106. Oscilloscope 195a is controlled by control signals 195e, which are generated by workstation 197 and transferred to acquisition electronics through control signals 196. Status signals and Data from oscilloscope 195a are transferred to workstation 197 using data paths 195e and 196. Signal generator 195b is controlled by control signals 195f, which are generated by workstation 197 and transferred to acquisition electronics through control signals 196. Status signals from signal generator 195b are transferred to workstation 197 through data paths 195f and 196.

Signal generator 195b is used to generate laser chopping pulses 195g which are transferred to laser source 120 through control signal path 105. Chopping signal 195g is a series of variable width and delay pulses that are synchronized to the DUT signal(s) of interest, via, in an embodiment, trigger signal 198, and optionally with the aid of clock signal 106. In an embodiment, signal generator 195b can be programmed to drive modulator driver 120d such that laser pulses 120j are shaped to tailor the response of the DUT and/or the photodetector 190 to the pulsed laser radiation.

CW-LVP systems in general benefit from the use of commercially available real-time digital storage oscilloscopes. Hence, oscilloscope 195a can be one of several different real-time oscilloscopes offered by, for example, Tektronix, Agilent, or LeCroy. Programmable signal generator 195b is also available commercially from companies such as Stanford Research Systems or Tektronix. While it may be beneficial to use commercially available electronic equipment, it is not a requirement for the application of the CW-LVP described herein.

In an embodiment, AC signal 195c and DC signal 195d are both acquired by oscilloscope 195a. While it is sufficient to only acquire AC signal 195c to capture the necessary waveform information for LVP, capturing DC signal 195d is beneficial in a number of ways. Dividing AC signal 195c by DC signal 195d allows AC signal 195c to be normalized to account for varying amounts of incident laser power, varying reflectivity of the probe location in the DUT, and varying losses in the optical path of the LVP system. Capturing and displaying DC signal 195d allows DUT drift to be detected while an acquisition is in progress (versus stopping the acquisition and imaging the DUT with the microscope to directly detect drift).

Laser voltage probing requires the use of a separate electrical trigger events 195h to trigger the waveform acquisition by oscilloscope 195a because the SNR of a single waveform measurement is too low for accurate triggering on the measured signal itself. This trigger signal may be supplied directly to the oscilloscope as trigger event 195h, or may be generated internally by the oscilloscope using a combination of both trigger event 195h and clock pulses 195i using the advanced triggering capabilities commonly available in modern oscilloscopes. Oscilloscope 195a may include triggering capabilities that allow, for example, the triggering circuitry of the oscilloscope to be only ‘armed’ with trigger event 195h but actually triggered by (i.e., measure time relative to) a transition of one of the clock pulses 195i. Other advanced triggering modes may be available in, and used by, oscilloscope 195i.

FIG. 2C shows a block diagram of another embodiment of acquisition electronics 195. In other embodiments, acquisition electronics 195 may not have all of the elements or features listed and/or may have other elements or features instead of or in addition to those listed. The primary difference between the embodiments illustrated in FIG. 2C and FIG. 2B is that in the embodiment of FIG. 2C the signal generator 195b is triggered using a programmable output of oscilloscope 195a that has been programmed to output trigger signal 195h. Trigger output 195h is synchronized to the actual start of an acquisition by oscilloscope 195a. Dead time in oscilloscopes prevent the oscilloscope from acquiring data on every trigger event 195h. By triggering signal generator 195b using trigger output 195h instead of trigger signal 198 (with or without aid of clock signal 106) the DUT will be irradiated only when the oscilloscope is actually acquiring data.

Depending on the rate of trigger events 195h, this may further reduce laser radiation incident on DUT by approximately 2× or more.

FIG. 2D shows a block diagram of an embodiment of DUT stimulus 165. DUT stimulus 165 includes ATE tester 165a and load board 165b. In other embodiments, DUT stimulus 165 may not have all of the elements or features listed and/or may have other elements or features instead of or in addition to those listed. ATE tester 165a generates and receives test signals 165c. Test signals 165c are routed through load board 165b which configures the signals mechanically and electrically for the particular DUT package. The DUT is driven by drive signals 167. In an embodiment, ATE tester 165a also generates trigger signal 197 and clock signal 106, which are used to synchronize the test pattern portion of interest to the LVP system's acquisition electronics. In an embodiment, trigger signal 197 is generated by DUT, but routed through ATE tester 165a for buffering. In an embodiment, ATE tester 165a generates a repetitive test pattern that exercises the DUT in a repetitive manner. In another embodiment, ATE tester 165a generates signals to enable and configure built-in self-test (BIST) features in the DUT which then generates the repetitive test pattern internally.

FIG. 2E shows a block diagram of another embodiment of DUT stimulus 165. In other embodiments, DUT stimulus 165 may not have all of the elements or features listed and/or may have other elements or features instead of or in addition to those listed. Computer workstation 165d interfaces to applications board 165e through signal bus 165f. Signal bus may be a standard personal computer bus such as PCI express, or USB, for example. Applications board may be a personal computer (PC) motherboard or a PC graphics board, for example. Clock signal may be from a crystal oscillator on the applications board, or may be an internal clock signal of the DUT, routed out through the applications board. Trigger signal may be an event programmed to be output from the DUT through a test pin and routed through applications board 165e, for example. There are many ways to generate trigger 197 and optional clock signal 106 that can be used to synchronize the Laser source and/or LVP acquisition electronics to the DUT signal(s) of interest.

FIG. 2F shows a block diagram of an embodiment of photodetector 190. Photodetector 190 includes photoreceiver 190b, RF bias-T 190c, RF electronic amplifier 190d, DC amplifier 190e, and high pass filter 190m. In other embodiments, photodetector 190 may not have all of the elements or features listed and/or may have other elements or features instead of or in addition to those listed. Reflected laser beam 170 is converted by photoreceiver 190b to a representative electrical signal 190g. Electrical signal 190g is passed through RF Bias-T 190c which splits the electrical signal into two components—an AC component 190h and a DC component 190j. AC component 190h is further amplified by RF amplifier 190d to give amplified AC signal 190i, while DC component 190j is further amplified by DC amplifier 190e to give amplified DC signal 190k. In accordance with an embodiment, amplified AC signal 190i is filtered using high-pass filter 190m to form filtered AC signal 190n. High-pass filtering is performed to remove at least a portion of the low frequency modulations in reflected laser beam 170 that is caused by the transient effects of the pulsed laser radiation. Filtered AC signal 190n and amplified DC signal 190k are transferred through electrical output signal 107 to acquisition electronics 195.

In an embodiment, an optical amplifier may be used to supplement or replace electronic amplifiers. Optical amplifier would be place before photoreceiver 190b to amplify the reflected laser beam 170 before conversion to an electrical signal. The need for an optical amplifier depends on the conversion gain of photoreceiver 190b, the amplitude of the reflect laser power 170, and the maximum power specification of 190b, for example. The need for RF amplifier 190d depends on the level of AC signal 190h and the sensitivity of the front-end of oscilloscope 195a in acquisition electronics 195. In an embodiment, no RF amplifier 190d is used. In an embodiment, no DC amplifier 190e is used. In an embodiment, only photoreceiver 190b is used. As mentioned above, it is advantageous to capture both the RF and DC components of reflected laser beam 170, but capturing both the RF and DC components of reflected laser beam 170 is optional. In an embodiment, no high-pass filter 190m is used.

AC frequency range extends to the highest frequency of interest in the LVP measurement (typically up to 1-20 GHz), while the lowest frequency may be about 1-1000 kHz. The DC frequency range extends from DC to typically 1-1000 kHz. The frequency that divides the AC and DC ranges is determined by RF bias-T 190c, but the AC and DC ranges can be further narrowed by the frequency responses of RF amplifier 190d and DC amplifier 190e, respectively. In accordance with one embodiment of this invention, the lower limit of the AC frequency range may be selected to be above the thermal time constant of the DUT under laser irradiation to filter out some of the transient effects of pulsing the laser beam. In other embodiments, filtering is performed digitally in the computer workstation 197.

FIG. 2G shows a block diagram of another embodiment of photodetector 190. In this embodiment, AC and DC components of reflected laser signal 170 are generated by optically splitting amplified laser signal 190f using beam splitter 190m, instead of electrically splitting them (using RF bias-T 190c, FIG. 2E, for example). Since DC signals are easier to amplify with low noise, beam splitter can have a split ratio that diverts 5% of amplified laser beam 190f into pick-off beam 190r and 95% maintained in main beam 190q. Main beam 190q is converted into AC electrical signal 190s using photoreceiver 190n, while pick-off beam 190r is converted separately into DC electrical signal 190v by DC photoreceiver 190p. Additional amplifiers 190d and 190w may be used to further amplify AC and DC signals 190s and 190v, respectively to give amplified AC and DC signals 190t and 190x, respectively. This embodiment allows the frequency ranges of AC signal 190s and DC signal 190v to be set independently of each other, which can be useful, for example, if DC electrical signal 190v is also used to generate the reflected light signal used for LSM imaging as well as LVP waveform acquisitions. For LSM imaging, ideally, upper limit of frequency response of DC electrical signal 190v extends to about 1 MHz to accommodate the fastest LSM scan rate, while it may be advantageous to set lowest frequency limit of AC signal 190s to be less than 1 MHz to allow probing of low frequency signals. Other embodiments are possible that do not use one or more of optical amplifier 190a, RF amplifier 190d, and DC amplifier 190w. An embodiment places a high-pass filter after RF amplifier 190d to filter at least some of the transient response of reflected laser beam 170 that are caused by pulsing of the laser source.

FIG. 2H shows a block diagram of an embodiment of microscope optics 130 that is based on use of a laser scanning microscope. In other embodiments, microscope optics 130 may not have all of the elements or features listed and/or may have other elements or features instead of or in addition to those listed.

Microscope optics 130 includes photon routing optics 130a which splits a portion of incoming laser beam 110 into pick-off beam 130d which is detected by incident power monitor 130e. The remainder of laser beam 110 forms the outgoing portion of main beam 130b, which is directed to beam scanning module 130c. FIG. 2H shows one possible implementation for a chopped CW system. Photon input/output module 130a separates reflected laser beam 170 from incident laser beam 110. Photon input/output module 130a may be a beam splitter, or a Polarization Difference Probing (PDP) optics, or some other optical arrangement. Beam scanning module 130C has x-y beam scanning mechanism (such as a pair of galvo-mirrors commonly used in laser scanning microscopes) to raster scan the laser beam (for imaging) and to ‘vector’ the beam to a fixed position in the DUT for probing. Galvo-mirrors deflect incoming portion of main beam 130b into outgoing portion of scanned laser beam 130f.

Beam manipulation optics 130g may include optics to reshape the beam into manipulated beam 130h to tailor the beam for microscope objective lens 140, which is used for both imaging and for probing. In one embodiment, beam manipulation optics 130g includes a scan lens and a tube lens arranged to form a telescope arrangement. Laser radiation 150 reflected by the DUT and re-collected by objective lens 140 re-enters microscope optics and retraces the input path through beam manipulation optics 130g, beam scanning module 130c and photon input/output optics 130a where the laser radiation is diverted from incoming beam path to form reflected laser beam 170. In an embodiment, diversion of reflected laser beam 150 into reflected laser beam 170 is accomplished though the use of quarter wave plate in beam manipulation optics 130g together with polarizing beam splitter in photon input/output optics 130a. In another embodiment, faraday isolator is used to divert reflected laser beam 150. Beam manipulation optics 130g might be a Scan Lens plus Tube Lens in a ‘telescope’ arrangement with or without a quarter wave plate, or might include a Wollaston prism or a Michelson interferometer. Other optical arrangements may also be used.

FIG. 2I shows a block diagram of an embodiment of a workstation 200 used in Laser Voltage Probing system 100 of FIG. 1. Workstation 200 may include output system 202, input system 204, memory system 206, processor system 208, communications system 212, and input/output device 214. In other embodiments, workstation 200 may include additional components and/or may not include all of the components listed above.

Work stations 200 is an embodiment of workstation 197. Output system 202 may include any one of, some of, any combination of, or all of a monitor system, a handheld display system, a printer system, a speaker system, a connection or interface system to a sound system, an interface system to peripheral devices and/or a connection and/or interface system to a computer system, intranet, and/or interne, for example. Output system 202 may send control signals and/or other signals to acquisition electronics 195. Output system 202 may also send control signals and/or other signals to other components in a LVP system.

Input system 204 may include any one of, some of, any combination of, or all of a keyboard system, a mouse system, a track ball system, a track pad system, buttons on a handheld system, a scanner system, a microphone system, a connection to a sound system, and/or a connection and/or interface system to a computer system, intranet, and/or interne (e.g., IrDA, USB), for example. Input system 204 may receive data and/or other signals from acquisition electronics 195. Input system 204 may also receive data and/or other signal from other components in a LVP system.

Memory system 206 may include, for example, any one of, some of, any combination of, or all of a long term storage system, such as a hard drive; a short term storage system, such as random access memory; a removable storage system, such as a floppy drive or a removable drive; and/or flash memory. Memory system 206 may include one or more machine-readable mediums that may store a variety of different types of information. The term machine-readable medium is used to refer to any medium capable of carrying information that is readable by a machine. One example of a machine-readable medium is a computer-readable medium. Memory system 206 stores machine instructions for controlling the process, which may include instructions for chopping the laser signal and determining the intensity of the signal.

Processor system 208 may include any one of, some of, any combination of, or all of multiple parallel processors, a single processor, a system of processors having one or more central processors and/or one or more specialized processors dedicated to specific tasks. Processor 208 implements the instructions stored in memory system 206, which may include instructions to control acquisition electronics 195, to chop the laser beam, to control the intensity of the laser beam, to analyze data related to the modulations in reflected laser beam 170, and/or other instructions.

Communications system 212 communicatively links output system 202, input system 204, memory system 206, processor system 208, and/or input/output system 214 to each other. Communications system 212 may include any one of, some of, any combination of, or all of electrical cables, fiber optic cables, and/or means of sending signals through air or water (e.g. wireless communications), or the like. Some examples of means of sending signals through air and/or water include systems for transmitting electromagnetic waves such as infrared and/or radio waves and/or systems for sending sound waves.

Input/output system 214 may include devices that have the dual function as input and output devices. For example, input/output system 214 may include one or more touch sensitive screens, which display an image and therefore are an output device and accept input when the screens are pressed by a finger or stylus, for example. The touch sensitive screens may be sensitive to heat and/or pressure. One or more of the input/output devices may be sensitive to a voltage or current produced by a stylus, for example. Input/output system 214 is optional, and may be used in addition to or in place of output system 202 and/or input device 204.

FIG. 2J shows one example of device under test 160. Incident laser beam 150 is directed to the NFET (n-type field effect transistor) drain depletion region 160a of CMOS (complementary metal oxide semiconductor) inverter 160b. Electrical switching activity on inverter input 160c causes charge density in NFET drain depletion region 160a to vary. This produces a modulation in reflected laser beam 150 that can be detected by laser voltage probing.

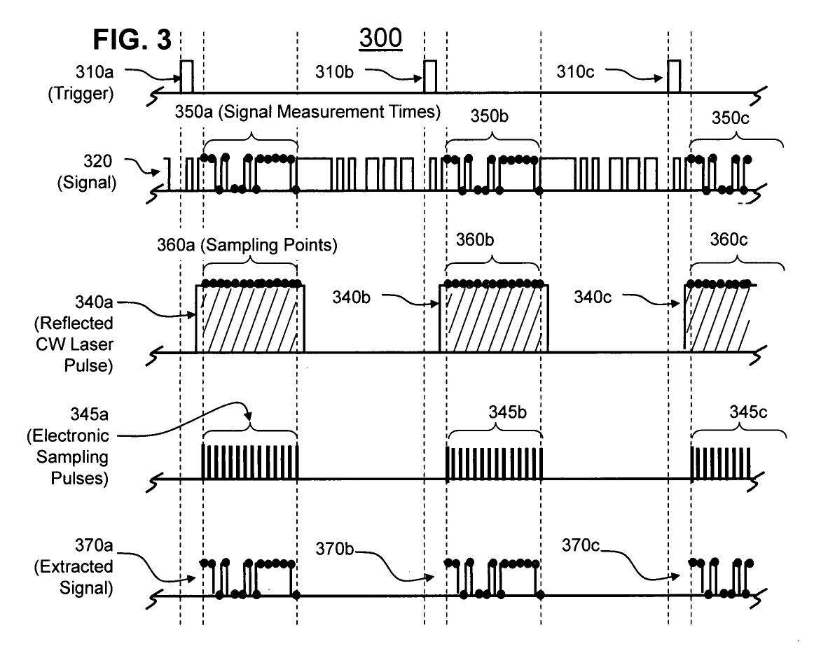

FIG. 3 shows timing diagram 300 of an embodiment of Laser Voltage Probing with Chopped CW Laser and with Real-Time Sampling. FIG. 3 shows trigger events 310 a, b, and c, repetitive signal 320, reflected chopped CW laser pulses 340 a, b, and c, series of electronic sampling pulses 345 a, b, and c, corresponding series of sampling points 350 a, b, and c, corresponding series of signal measurement times 360 a, b, c, and extracted waveform data 370 a, b, c respectively. In other embodiments timing diagram 300 may not have all of the elements or features listed and/or may have other elements or features instead of or in addition to those listed.

Trigger events 310 a, b, and c are created for synchronizing repetitive signals. Trigger events 310 a, b, and c are events that may be part of trigger signal 198 (which was discussed in conjunction with FIG. 1, FIG. 2D, and FIG. 2E). For simplicity, trigger events are depicted as single pulses. Signal 320 has a repetitive portion that is synchronized to a trigger events 310 a, b, and c. Trigger events 310 a, b, c may mark the start of the each repetition of the repetitive portion of the signal 320. In LVP system 100, laser pulses 340 are a CW laser beam that is chopped, generating pulses that are sent to, and reflected from, DUT 160. The laser pulses are synchronized to the signal by way of trigger events 310 a, b, c, respectively. Acquisition electronics 195 generate a series of electronic sampling pulses 345 a, b, and c, to measure the intensity fluctuations in laser pulses 340 a, b, and c, respectively (after the pulses have been converted to an electrical representation by photodetector 190). The series of sampling pulses occurs at a rate sufficiently high to perform real-time sampling of the intensity fluctuations. Series of sampling pulses 345 a, b, and c, correspond in time to series of sampling points 350 a, b, and c, and to series of signal measurement times 360 a, b, and c. Each extracted signal 370 a, b, and c, are generated as a result of the series of sampling pulses 345 a, b, and c causing measurements to be made on laser pulses 340 a, b, and c, respectively. Signal measurement times 360 a, b, and c, occur over intervals during which it is desired to take a measurement of the electrical activity occurring in DUT 160. The generated laser pulses 340 a, b, and c overlap the desired measurement intervals, 360 a, b, and c, respectively. By chopping the CW laser beam, the heating effects of the beam on the DUT 160 can be reduced, allowing more incident CW laser power to be used during the signal measurement intervals. Increasing the incident CW laser power increases the reflected CW laser power, thereby reducing the effects of shot noise (the statistical fluctuations in the number of photons measured).

To estimate an upper limit to the improvement that can be realized, take the simple example where the device damage threshold is 10 mW of average laser power, the total test pattern length is 100 microsecond, and the desired measurement time span is 1 microsecond. Then, to maintain the average laser power at the damage threshold using the current art technique of continuously illuminating the DUT, only 10 mW of power can be used during the actual measurement period. The laser power over the measurement time span can be increased by 100 times if the CW beam is chopped to form a pulse of 1 microsecond duration, with the laser beam off for the remaining 99 microseconds (beam ‘duty-cycle’ of 1%). In both cases, the average power delivered to the DUT is the same, but pulsing the laser allows measurements to be made 100 times faster.

In practice, it may be desirable and/or necessary to make more modest increases in the laser power. For a damage mechanism based on temperature rise (heating), the damage threshold is expected to depend on factors other than just average power. Damage threshold may also depend on peak power, pulse period, thermal conductivity of the DUT, laser power density, etc, since all these factors may affect the temperature rise within the DUT. An empirically determined model that gives the relationship between parameters of LVP system 100 (FIG. 1) and the amount that the laser power may be increased (compared to were no chopping present) can be used to either automatically set peak power in a system, or to give the user guidance on how much peak power to use when probing under the particular test conditions (measurement time-span of interest, test pattern length) the user has set up.

Note that the CW laser pulses, pulses 340 a, b, and c (FIG. 3) are purposely shown to extend beyond the signal measurement interval (though not necessarily with actual proportions). It may be desirable in some embodiments of this invention to allow the DUT 160 and/or electronics to stabilize before the measurements are taken.

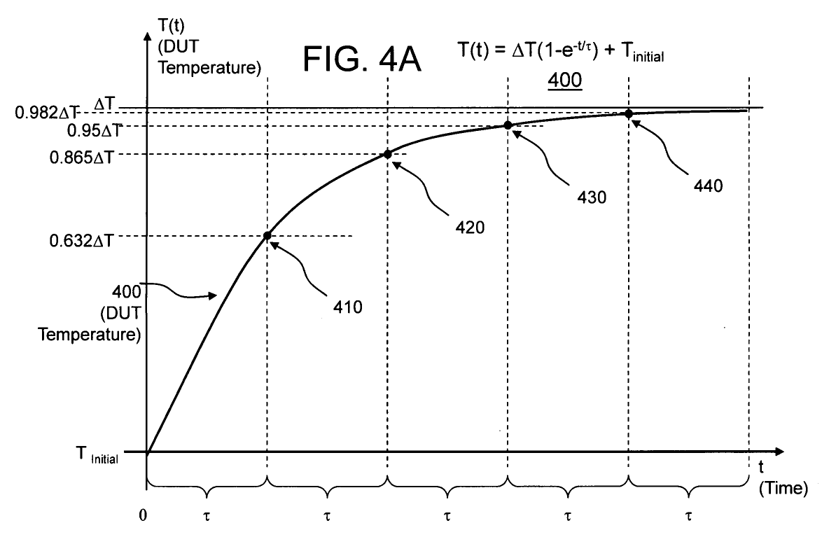

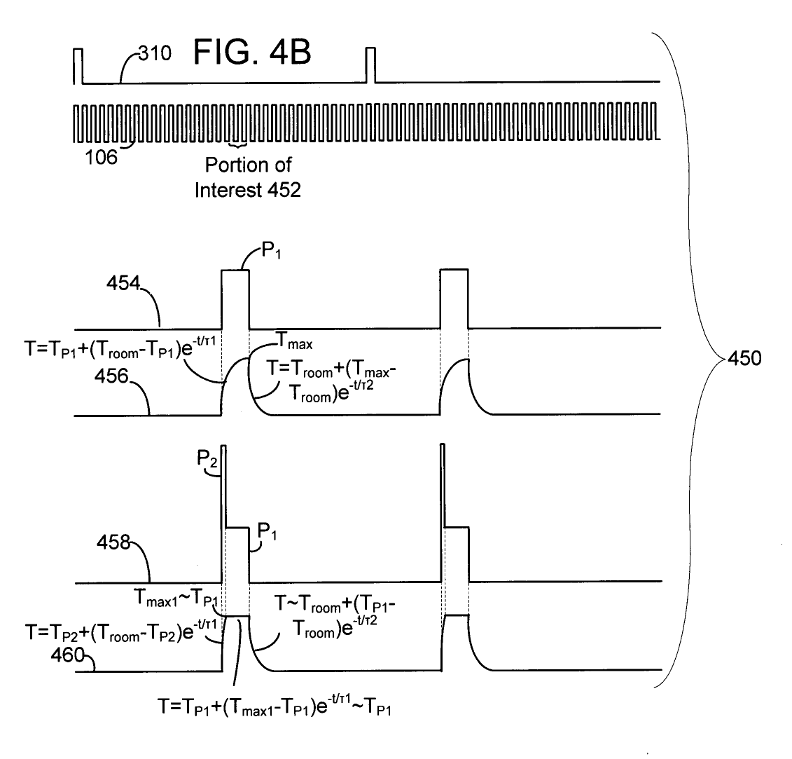

FIG. 4A shows a plot 400 illustrating an example of the temperature response of DUT 160 (FIG. 1) to pulses 340 a, b, and c (FIG. 3). In other embodiments plot 400 may not have all of the elements or features listed and/or may have other elements or features instead of or in addition to those listed.

Horizontal axis represents time, t, vertical axis represents the DUT temperature, T(t), at the region of laser illumination. DUT 160 is at some constant, initial temperature, Tᵢₙᵢₜᵢₐₗ, before laser illumination. Laser illumination starts at time t=0. ΔT is the total temperature change due to laser illumination, assuming equilibrium conditions with constant illumination. The temperature as a function of time is given by the equation T(t)=ΔT(1-e^{-t/τ}) Tᵢₙᵢₜᵢₐₗ, where ΔT=Tₛₐₜ−Tᵢₙᵢₜᵢₐₗ, and where Tₛₐₜ depends on the power of the laser radiation. The temperature Tₛₐₜ is the temperature that irradiated portion of DUT 160 asymptotically tends to when the continuous wave laser is irradiating DUT 160. If the DUT is initially at room temperature and then heated by the laser, Tᵢₙᵢₜᵢₐₗ is room temperature and Tₛₐₜ>Tᵢₙᵢₜᵢₐₗ. If the DUT is already heated to a given temperature by the laser radiation, and then the laser is shut off, then Tₛₐₜ is room temperature and Tₛₐₜ<Tᵢₙᵢₜᵢₐₗ. The equation T(t)=ΔT(1-e^{-t/τ})+Tᵢₙᵢₜᵢₐₗ can also be written as T(t)=Tₛₐₜ−ΔTe^{-t/τ}. The relaxation time constant τ=C/hA, where h is the heat transfer constant, A is the cross sectional area through which the heat travels, C is the total heat capacity, and the heat capacity of a system may be further represented by its mass-specific heat capacity cₚ multiplied by its mass m, so that the time constant τ is also given by mcₚ/(hA). While heating the dominant contribution to τ is from the laser, and consequently, A is the cross section of the laser beam. As an approximation, the cooling may be considered to occur during two stages. During a first stage the heat dissipates throughout DUT 160 and during a second stage the heat leaves DUT 160 into the air or a heat sink or the chip carrier. During the first stage, A is the surface area of the volume heated by the laser while the laser was on, and C is the heat capacity of the silicon. During the second stage A is the surface area of DUT 160, and C is the heat capacity of air, for example. For simplicity, in the discussion that follows, it will be assumed that one of these two cooling stages dominates, and the relaxation constant while heating will be represented by τ1 and the relaxation constant during cooling will be represented by τ2.

Plot 400 assumes laser pulse width is many times greater than the thermal time constant, τ, which characterizes the situation. 410, 420, 430, and 440 indicate the DUT temperature after 1, 2, 3 and 4 time constants have passed, respectively. After 4 time constants have passed, the temperature reaches 98.2% of its final value. Since the index of refraction varies with DUT temperature, the effects on the LVP measurement caused by the temperature rise may need to be accounted for.

FIG. 4B shows a plot 450 illustrating an example of the temperature response to the chopped continuous wave laser signal. Plot 450 includes trigger signal 310, clock signal 106, chopped continuous wave signal 454 having laser pulse of power P₁, thermal response 456, chopped continuous wave signal 458 having laser pulse of power P₁ during a first portion and power P₂ during a second portion, and thermal response 460. In other embodiments plot 450 may not have all of the elements or features listed and/or may have other elements or features instead of or in addition to those listed.

Trigger signal 310 and clock signal 106 were discussed in conjunction with FIGS. 3 and 1, respectively. Portion of interest 452 is the portion of clock signal 106 that corresponds to the repetitive DUT signal(s) of interest. The first and last clock pulse of portion of interest 452 may be used to indicate when to pulse laser source 120. Chopped continuous wave signal 454 has laser pulse that delivers power P₁ to the DUT 160. The pulse begins before portion of interest 452 (e.g., one clock signal earlier) and ends after portion of interest 452 (e.g., one clock signal earlier). Thermal response 456 is the thermal response of DUT 160 to chopped continuous wave signal 454. During each laser pulse, having power P₁, the temperature of DUT 160 rises according to equation T=T_{P1}+(Tᵣₒₒₘ−T_{P1})e^{-t/τ1}. At the end of the laser pulse, the temperature has risen to Tₘₐₓ. After the laser pulse ends, the temperature drops according to equation T=Tᵣₒₒₘ+(Tₘₐₓ−Tᵣₒₒₘ)e^{-t/τ2}.

Since the index of refraction of the DUT varies with DUT temperature, the effects on the LVP measurement caused by the rising temperature may need to be accounted for In an embodiment, to reduce and possibly minimize the effects caused by the rising temperature, chopped continuous wave 458 is used instead of chopped continuous wave 454. Chopped continuous wave 458 has laser pulses that each have a first portion in which power P₂ is delivered by the laser beam to DUT 160 (FIG. 1), which is followed by a second portion in which power P₁ is delivered. Thermal response 460 is the thermal response of DUT 160 to chopped continuous wave 458. While power P₂ is applied, DUT 160 heats up according to equation T=Tₚ₂+(Tᵣₒₒₘ−T_{P2})e^{-t/τ1}. Power P₂ is applied until the temperature reaches Tₘₐₓ₁˜T_{P1}, which is the temperature that DUT 160 approaches and is stable at while power P1 is applied. In an embodiment, the temperature Tₘₐₓ₁ is expected, and is intended, to be equal to T_{P1}. However, if Tₘₐₓ₁ and T_{P1} are not equal, while power P₁ is applied, the temperature of DUT 160 is given by T=T_{P1}+(Tₘₐₓ₁−T_{P1})e^{-t/τ1}. After the laser pulse ends, the temperature of DUT 160 is given by T˜Tᵣₒₒₘ+(T_{P1}−Tᵣₒₒₘ)e^{-t/τ2}.

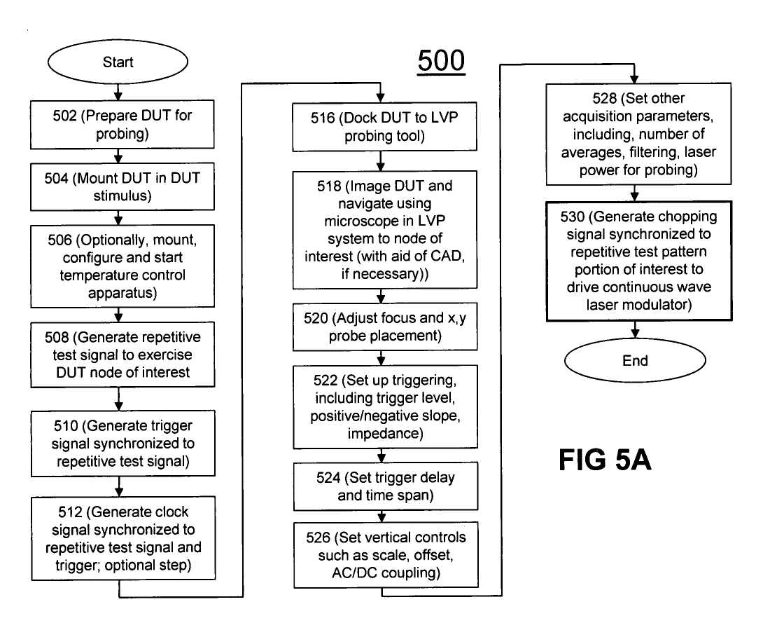

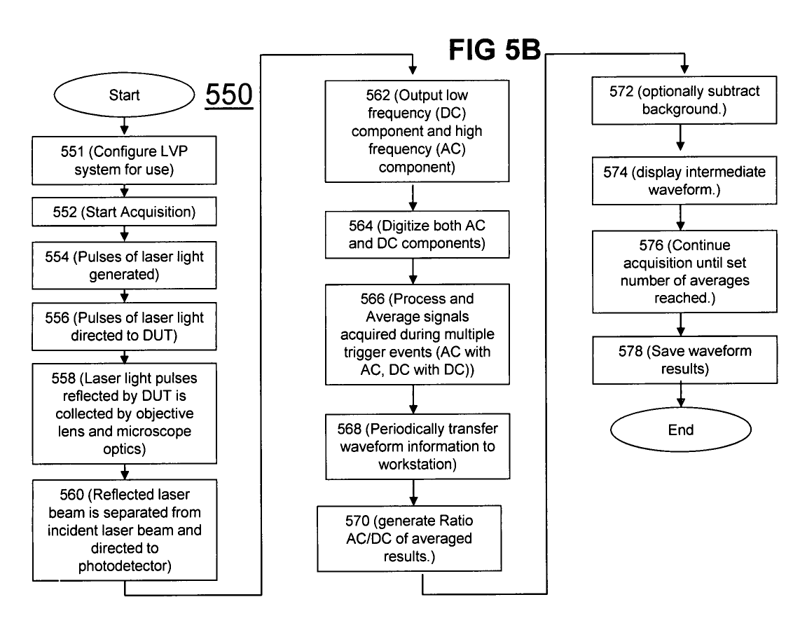

FIG. 5A shows a flowchart of an embodiment of a method 500, which is a method of configuring a LVP system for probing a DUT with a chopped laser beam. In step 502, DUT is prepared for probing. This step may include thinning and polishing the DUT and/or applying an anti-reflection coating on the DUT as necessary for use with microscope objective lens 140 (FIG. 1). In step 504, the DUT is mounted in DUT stimulus 165 (FIG. 1), which may consist of ATE tester 165a with load board 165b (FIG. 2D), or computer workstation 165d with applications board 165e (FIG. 2E), or other means to stimulate DUT for probing. In optional step 506, the DUT is mounted, configured, and a temperature control apparatus is started. Optional step 506 may be required if the operating DUT dissipates excessive power, which would cause damage to the DUT if left uncooled and/or if testing the DUT requires the DUT to be held at a particular temperature. In step 508, DUT stimulus 165 (FIG. 1) is programmed to cause the DUT circuitry of interest to be exercised repetitively over the signal(s) of interest. In step 510, DUT and/or DUT stimulus is programmed to output trigger signal 198 (FIG. 1, FIG. 2B, FIG. 2C, FIG. 2D, and FIG. 2E) that is synchronized with DUT signal(s) of interest. In optional step 512, DUT and/or DUT stimulus is programmed to output clock signal 106 (FIG. 1, FIG. 2B, FIG. 2C, FIG. 2D, FIG. 2E) which may be used in conjunction with trigger signal 198 to generate laser chopping pulse 195g (FIG. 2B, FIG. 2C) that is synchronized with DUT signal(s) of interest, and to serve as a synchronized time reference for oscilloscope 195a (FIG. 2B, FIG. 2C). In step 516, the DUT is interfaced to LVP system 100. Step 516 may include the steps of mechanical docking, and connecting of electrical trigger signal 198 and optional clock signal 106 to LVP system 100. In step 518, the DUT is imaged using microscope optics 130 and objective lens 140 (FIG. 1) to locate the circuitry of interest for probing. Computer aided design (CAD) information of the DUT may be used if required. Once the circuitry of interest is located, the laser spot is focused and positioned at the node of interest in step 520. The triggering circuitry of oscilloscope 195a (FIG. 2B, FIG. 2C) is configured in step 522, which involves setting up an advanced triggering mode if necessary, and which involves setting parameters such as the trigger level, impedance, slope, and coupling. After oscilloscope 195a is set up to trigger properly, the horizontal scope settings are configured in step 524. Configuring the horizontal scope settings may involve setting the trigger delay and acquisition time span to capture the DUT signal(s) of interest. The vertical controls of oscilloscope 195a are configured in step 526. Settings generally differ for the AC (195c, FIG. 2B, FIG. 2C) and DC (195d, FIG. 2B, FIG. 2C) components of the photodetector output signal 107 and depend on their signal levels. Other acquisition parameters are set in step 528. The acquisition parameters may include parameters such as laser power level, number of waveforms to accumulate and/or average, and waveform filtering. Step 530 may include programming the programmable signal generator 195b (FIG. 2B, FIG. 2C) to output laser chopping pulses 195g (FIG. 2B, FIG. 2C) synchronized to, or otherwise correlated to, the repetitive DUT signal(s) of interest. Timing, duration, amplitude, and shape of the resultant laser pulses 120j (FIG. 2A) depend on the acquisition time span and trigger delay set in step 524 and the trigger rate of trigger signal 198 (FIG. 1, FIG. 2B, FIG. 2C) and damage threshold of the DUT. In an embodiment, pulse shape is set to minimize the amplitude of the impulse received by DUT 160 and photodetector 190. In an embodiment, pulse shape is set to accelerate the reaching of thermal equilibrium in the DUT.

FIG. 5B shows a flowchart of an embodiment of a method 550, which is a method of using a LVP system 100 for probing a DUT with a chopped laser beam. LVP system 100 is configured for use in step 551. Configuration includes all the steps in method 500. The acquisition is started in step 552. Laser light pulses are generated in step 554 by laser source 120 (FIG. 1, FIG. 2A) under control of laser control signals 105 (FIG. 1, FIG. 2A, FIG. 2B, FIG. 2C). In step 556, the laser light pulses are directed to DUT via microscope optics 130 (FIG. 1, FIG. 2H) and objective lens 140 (FIG. 1). In step 558, laser light pulses reflected by DUT are re-collected by objective lens 140 and retrace their path into microscope optics 130. In step 560, laser light pulses are separated out of main beam path and directed to photodetector 190 (FIG. 1, FIG. 2F, FIG. 2G). Photodetector 190 outputs AC and DC component of signal in step 562. Real-time digital storage oscilloscope 195a (FIG. 2B, FIG. 2C) in acquisition electronics 195 (FIG. 1), digitizes the AC and DC components in step 564. The digitization may be synchronized to repetitive DUT signal(s) of interest via trigger signal 198 and optional clock signal 106 (FIG. 1, FIG. 2B, FIG. 2C, FIG. 2D, FIG. 2E). Waveform data is generated by the digitization of the information in each laser pulse. In step 566, waveform data are accumulated and/or averaged over multiple trigger events. In an embodiment, the oscilloscope just accumulates the data in the form of a 2-D array of bins that plot amplitude versus time. Any bin that is ‘hit’ by a waveform causes the number of ‘hits’ to be incremented in that bin. Collecting the data in bins reduces and possibly minimizes the amount of data that has to be transferred and therefore reduces and possibly minimizes the dead time when compared to a method in which bins are not used. Averaging and/or accumulation of the AC with AC data and the DC with DC data over the repeated signal(s) of interest is performed to increase the final waveform's SNR. In step 568, the averaged and/or accumulated waveform data are periodically transferred to workstation 197 for further processing, display, and storage. Periodic transfers are performed so that the user of the LVP system 100 can monitor the progress of the acquisition. Processing may involve applying additional filtering, such as boxcar averaging, or may involve more complex operations, such as calculating the weighted average of a two-dimensional histogram of accumulated data. In step 570, the optional step of taking the ratio of AC to DC waveform amplitude at each time bin is performed to normalize the waveform amplitude. In optional step 572, waveforms are processed to subtract, divide, or otherwise remove the signal background caused by the transient effects of the laser pulses. In step 574, intermediate waveforms (e.g., waveforms generated with less than the final number of averages and/or accumulations desired) are displayed on workstation monitor to allow the waveform acquisition process to be monitored. If the LVP user sees that the intermediate waveform results are not as expected, the user can terminate the acquisition and reconfigure the LVP system 100 as necessary to correct any errors. In step 576, the waveform acquisition proceeds until desired number of averages and/or accumulations is reach. Waveforms are saved on workstation 197 (FIG. 1) in step 578.

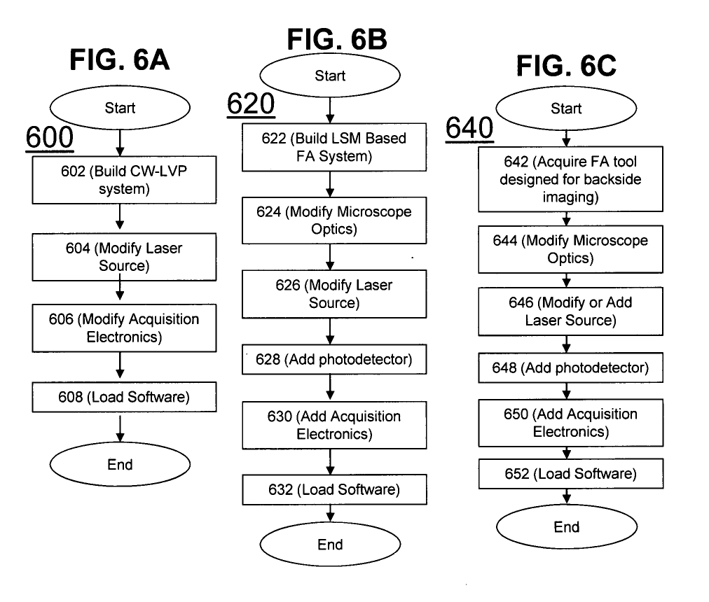

FIG. 6A shows a flowchart of an embodiment of a method 600, which is a method of making the LVP system 100 of FIG. 1. In step 602, a CW-LVP system is built. In step 604, the laser source is modified by adding means to generate laser pulses, such as the addition of modulator driver 120d and acousto-optic modulator 120c (FIG. 2A). In step 606, the acquisition electronics are modified to incorporate programmable signal generator 195b (FIG. 2B, FIG. 2C). In step 608, software is loaded onto acquisition electronics 195, workstation 197, and/or signal generator 195b to control programmable signal generator 195b, and to incorporate additional processing, including, but not limited to, filtering and background subtracting, into signal processing routines in workstation 197 (FIG. 1).

FIG. 6B shows a flowchart of embodiment of method 620, which is another method of making the LVP system 100 of FIG. 1. In step 622, an LSM based failure analysis system is built. In step 624, the microscope optics are modified to route reflected laser beam 170 out from the incident laser beam (FIG. 1). In step 626, laser source is modified to incorporate a low noise laser (which may include laser head 120a and laser controller 120b of FIG. 2A) and acousto-optic modulator 120c and modulator driver 120d (FIG. 2A). In step 628, a photodetector 190 is added (FIG. 1, FIG. 2F, FIG. 2G). In step 630, acquisition electronics 195 (FIG. 1, FIG. 2B, FIG. 2C) is added. In step 632, software is loaded into acquisition electronics 195, workstation 197, and/or signal generator 195b that controls data acquisition electronics 195 and that processes, displays, and stores waveforms.

FIG. 6C shows a flowchart of embodiment of method 640, which is yet another method of making the LVP system 100 of FIG. 1. Method 640 is the same as method 620 except that the starting point is to acquire, instead of build an FA system, and the FA system may not be LSM based. If the FA system is not LSM based, step 644 involves incorporation of laser beam path into microscope optics. In step 646, laser source is modified to incorporate a low noise laser 120a and 120b (FIG. 2A) and acousto-optic modulator and modulator driver 120c and 120d, respectively (FIG. 2A). In step 648, a photodetector 190 is added (FIG. 1, FIG. 2F, FIG. 2G). In step 650, acquisition electronics 195 (FIG. 1, FIG. 2B, FIG. 2C) is added. In step 652, software is loaded into acquisition electronics 195, workstation 197, and/or signal generator 195b that controls data acquisition electronics 195 and that processes, displays, and stores waveforms.

In an embodiment, each of the steps of method 640 is a distinct step. In another embodiment, although depicted as distinct steps in FIG. 6, step 602-618 may not be distinct steps. In other embodiments, method 600 may not have all of the above steps and/or may have other steps in addition to or instead of those listed above. The steps of method 600 may be performed in another order. Subsets of the steps listed above as part of method 600 may be used to form their own method.

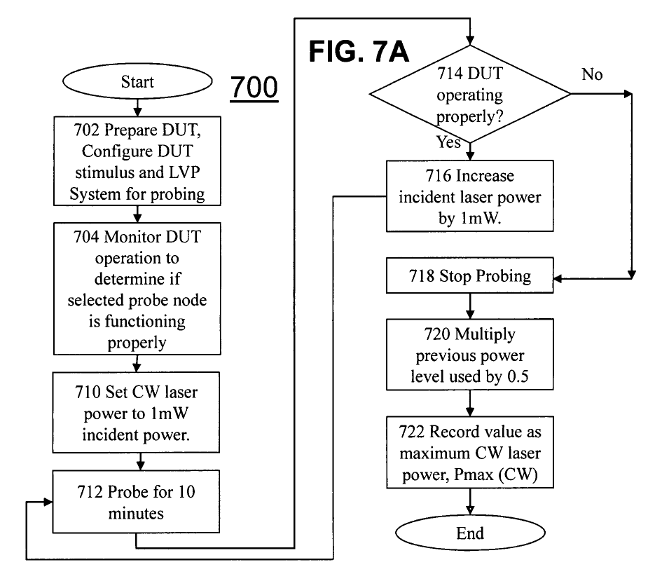

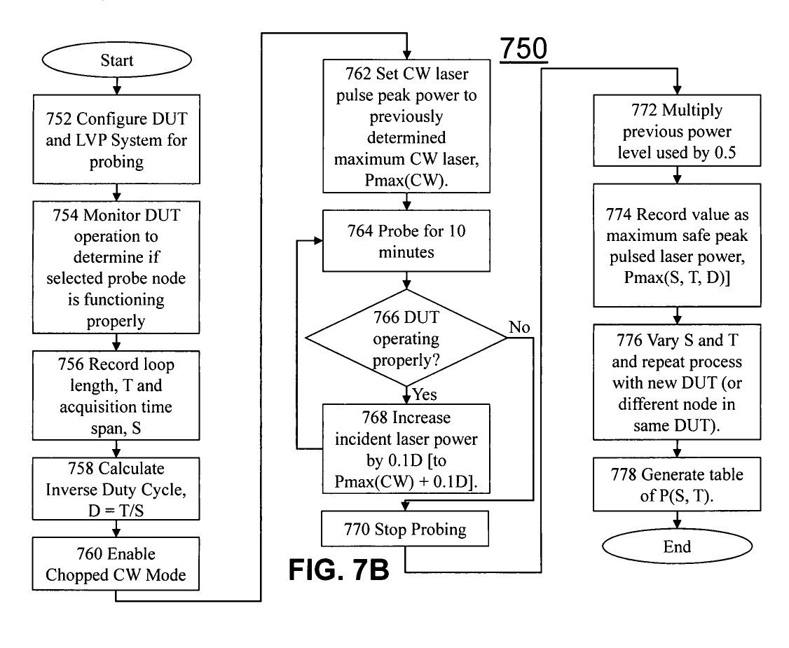

FIG. 7A is a flowchart of an embodiment of a method 700 of determining the damage threshold of a DUT irradiated with a CW laser beam. Method 700 may involve the LVP probing a node in a DUT with increasingly high CW laser power until node damage is sustained. In step 702, a DUT, DUT stimulus, and LVP system are set up for probing, as described in method 500, steps 502-528 (FIG. 5A). Since the purpose of method 700 is to determine the safe operating power in CW mode, step 530 may be skipped. In step 704 the DUT is monitored to determine that the selected probe node functions correctly before starting. In step 710 the CW laser power is set at an initial, conservative value of 1 mW. In step 712, probing commences for 10 minutes, a time duration typical for an LVP. In step 714, a decision is made, depending on whether the DUT has sustained damage during probing or not. If the DUT has sustained no detectable damage, then method 700 proceeds to step 716 where the laser power is increased by 1 mW, steps 712 and 714 are repeated. Returning to step 716, DUT damage may be determined by monitoring the electrical behavior of the DUT and/or by monitoring the LVP waveform to detect changes in the waveform shape, amplitude, and/or timing. If during step 716 DUT damage is detected, then method 700 continues with step 718 where probing is ceased. In step 720, to set a conservative probing power level, the power level which caused DUT damage is multiplied by 0.5 in step 720, which is used as the maximum probing power, and the value of the maximum probing power is recorded as Pmax(CW) in step 722.

In a different embodiment, factor to determine Pmax(CW) may be 0.75, 0.9, 0.25, 0.10, etc depending on the desired trade-off between minimizing the probability of DUT damage during prolonged probing (lower multiplicative values) versus the need to improve waveform SNR (higher multiplicative values).

In a different embodiment, probing time will be changed to match the typical probing time required to extract an LVP waveform with sufficient SNR.

In different embodiments, initial laser power and power increases may differ from the values given here.

In another embodiment, the node will be probed until maximum CW laser power of the LVP system is reached.

In yet another embodiment, the node will be probed until the power limit of photodetector 190 (FIG. 1, FIG. 2F, FIG. 2G) is reached.

In an embodiment, each of the steps of method 700 is a distinct step. In another embodiment, although depicted as distinct steps in FIG. 7A, step 702-722 may not be distinct steps. In other embodiments, method 700 may not have all of the above steps and/or may have other steps in addition to or instead of those listed above. The steps of method 700 may be performed in another order. Subsets of the steps listed above as part of method 700 may be used to form their own method.

FIG. 7B is a flowchart of an embodiment of a method 750 of determining the damage threshold of a DUT irradiated with a chopped CW laser beam. Procedure 750 is similar to procedure 700 for a CW laser beam, except that the loop length, acquisition time span, and beam duty cycle is varied along with peak CW laser pulse power. In step 752, a DUT, DUT stimulus, and LVP system is set up for probing, as described in method 500 (FIG. 5A). In step 754, the DUT is monitored to determine that the selected probe node functions correctly before starting. In step 756, the loop length, T, and acquisition time span, S, are record. In step 758, the inverse of the laser duty cycle, D=T/S, is calculated. In step 760 the chopping mode of the LVP system is enabled. In step 762 the peak CW laser power is set at an initial, conservative value equal to Pmax(CW) found in method 700. In step 764, probing commences for 10 minutes, a time duration typical for LVP. In step 766, a decision is made, as to whether the DUT has sustained damage during probing. If the DUT has sustained no detectable damage, then method 750 proceeds to step 768, where the laser power is increased by an amount equal to 10% of the inverse duty cycle, D, and steps 764 and 766 are repeated. In other embodiments, different increments are used instead of 10% of the duty cycle. Returning to step 768, DUT damage may be determined by monitoring the electrical behavior of the DUT and/or by monitoring the LVP waveform to detect changes in the waveform shape, amplitude, and/or timing. If in step 768, DUT damage has been detected, then method 750 proceeds to step 770 where probing is ceased. To set a conservative probing power level, the power level which caused DUT damage is multiplied by 0.5 in step 772, which is the maximum probing level for a chopped CW laser, and the maximum probing value for the chopped CW laser is recorded as Pmax(S, T) in step 774. Similar to step 722, in a different embodiments of step 774, factor to determine Pmax(CW) may be 0.75, 0.9, 0.25, 0.10, etc depending on the desired trade-off between minimizing the probability of DUT damage during prolonged probing (lower multiplicative values) versus the need to improve waveform SNR (higher multiplicative values). As indicated, Pmax(S, T) is a function of acquisition time span, S, and loop length, T. In step 776, S and T are varied, and the test is repeated using a new DUT, or a different node in the same DUT. Finally, in step 778, the values of Pmax(S, T) are tabulated. The table can be used manually to guide the LVP operator in setting the peak CW laser power to use in chopped mode, or the table can be used to generate a look-up table that is used by the LVP software to automatically set the laser power, depending on S and T.

In an embodiment, each of the steps of method 750 is a distinct step. In another embodiment, although depicted as distinct steps in FIG. 7B, step 752-778 may not be distinct steps. In other embodiments, method 750 may not have all of the above steps and/or may have other steps in addition to or instead of those listed above. The steps of method 750 may be performed in another order. Subsets of the steps listed above as part of method 750 may be used to form their own method.

Since damage threshold may vary depending on node size (for example, large signal buffers may be able to sustain more laser power before suffering detectable damage than smaller buffer) methods 700 and 750 may have to be used to determine maximum safe laser powers for the different types of nodes probed.

Since damage threshold may also vary depending on process technology (65 nm geometry devices might tolerate more laser power than 45 nm geometry devices, for example), methods 700 and 750 may have to be used to determine maximum safe laser powers for each process technology.

Each embodiment disclosed herein may be used or otherwise combined with any of the other embodiments disclosed. Any element of any embodiment may be used in any embodiment.

Although the invention has been described with reference to specific embodiments, it will be understood by those skilled in the art that various changes may be made and equivalents may be substituted for elements thereof without departing from the true spirit and scope of the invention. In addition, modifications may be made without departing from the essential teachings of the invention.

1. A method comprising:
applying at least one input signal to a device under test (DUT), the at least one input signal causing a response in at least one circuit element in the DUT over a first duration of time, the response has a first portion that is a portion of interest that occurs over a second duration of time that is less than the first duration of time, the first portion of the response indicating a behavior of a function of the DUT, of a section of the DUT, or of a component connected to the DUT;
the first portion of the response being repeated;
irradiating the DUT at a particular location of interest with laser radiation during at least a plurality of instances of the first portion;
not irradiating the DUT at the particular location of interest during a second portion of the response, which occurs during a portion of the first duration of time that is not during the second duration of time;
the second portion occurring for a third duration of time that occurs during the first duration of time, the second duration of time being before or after the third duration of time, the third duration of time being either a fixed or variable length of time;
and
a processor system including one or more processors analyzing measurements of fluctuations in the laser radiation caused by the DUT to determine the behavior of the function of the DUT or of the section of the DUT.

2. The method of claim 1, the irradiating of the DUT including at least irradiating with at least a probing power before the first portion and irradiating with the probing power during the first portion.

3. The method of claim 2, the second duration being most of a duration of time that is the duration of time of the irradiating of the DUT.

4. The method of claim 1, the analyzing including receiving the laser radiation with the fluctuation at a photo receiver;
the photo receiver converting the laser radiation to an electrical signal, which is discretized into data points; and
the irradiating of the first portion with laser radiation generating a plurality of data points.

5. The method of claim 1, the analyzing including comparing measurements of the fluctuations of the laser radiation to fluctuations of the laser that the portion of the response is expected to cause.

6. The method of claim 1, further comprising:
prior to taking measurements, irradiating the DUT with a CW laser pulse that has a duration of time that is greater than a relaxation time-constant for a rate of heating the DUT.

7. The method of claim 1, further comprising high-pass filtering signals from electronics of equipment therein rejecting low frequency changes in the signals.

8. The method of claim 1, the analyzing of the fluctuations in the laser radiation caused by the DUT including directing the laser radiation having the fluctuations upon a photo receiver, which in response generates an electrical signal representative of the laser radiation having the fluctuations to determine the behavior of the function of the DUT or of the section of the DUT;
the method further comprising high-pass filtering the electrical signal generated based on the photo receiver.

9. The method of claim 1, further comprising characterizing transient effects on measurements of the response of the DUT, subtracting an expected transient effect from the measurement of the response.

10. The method of claim 1, the DUT having at least:
a top side on which integrated circuit elements are located, and
a bottom side on which the integrated circuit elements are not located; and
the irradiating including irradiating through the bottom side of the DUT.

11. The method of claim 10, the analyzing including at least measuring fluctuations in a laser beam that is reflected out of the bottom and that results from the irradiating.

12. The method of claim 1, the irradiating and the not irradiating resulting from chopping a continuous laser beam.

13. The method of claim 1, further comprising:
irradiating the DUT with a laser at an amount of power that is higher than a probing power for a duration of time that is expected to raise the DUT to a temperature that the DUT is expected to remain while being irradiated with a laser at the probing power, after the DUT is expected to be at the temperature, lowering the laser power to the probing power and performing the analyzing.

14. The method of claim 1, the input test signal having a repetition period of between ten microseconds and ninety milliseconds; and the portion of interest repetition having a duration between 100 picoseconds and 1 microsecond.

15. The method of claim 1, the DUT having a threshold receivable power, where if the DUT is irradiated continuously at a location with laser radiation that delivers an amount of power that is greater than the threshold receivable power, the DUT will be damaged;
the irradiating of the DUT being with laser radiation that delivers an amount of power that is greater than the threshold receivable power;

16. The method of claim 1, the irradiating of the DUT at a location being with laser radiation that delivers an amount of power that is greater than a threshold power and less than or equal to the threshold power divided by the duty cycle.

17. The method of claim 1, the DUT having a relaxation time constant characterizing how fast temperature of the DUT rises during the irradiating, and the duration of the irradiating during each repetition being greater than twice the relaxation time-constant.

18. A machine readable medium storing thereon one or more machine instructions, which when implemented by a processor cause the method of claim 1 to be implemented.

19. A system comprising:
the machine readable medium of claim 18;
a laser source that generates the laser radiation;
microscope optics including at least an objective lens, the radiation from the laser source being directed through the microscope optics onto the DUT;
a photodetector that receives the laser radiation after the irradiating;
a stimulus that generates the inputs of the DUT and powers the DUT;
acquisition electronics for capturing the signal generated by the photodetector; and
the laser source being controlled by the acquisition electronics via control signals that synchronizes pulses from the laser source so that the irradiating of the DUT occurs during at least the second portion.

20. A method comprising:
applying at least one input signal to a device under test (DUT), the at least one input signal causing a response in at least one circuit element in the DUT, the response having at least one repetitive component, the at least one repetitive component indicating a function of the DUT or of a section of the DUT or of a component connected to the DUT;
irradiating at least one particular location on the DUT with laser pulses, the laser pulses synchronized to at least some occurrences of the at least one repetitive component, the laser pulses not irradiating the at least one particular location in the DUT continuously;
analyzing fluctuations in the laser radiation caused by the DUT to determine the behavior of the function of the DUT or of the section of the DUT, or of the component connected to the DUT, the analyzing including discretizing of the electrical representation of the fluctuations in the laser radiation, the discretizing including at least electronically measuring the electrical representation at a plurality of points within each laser pulse, the discretizing being synchronized to or otherwise correlated with the at least one repetitive component of the response in the DUT.

21. A method comprising:
applying at least one input signal to a device under test (DUT), the at least one input signal causing a response in at least one circuit element in the DUT, the response having at least one repetitive component, the at least one repetitive component indicating a function of the DUT or of a section of the DUT or of a component connected to the DUT;
irradiating at least one particular location on the DUT with laser pulses, the laser pulses synchronized to measurement activity of acquisition electronics;
in at least some occurrences of the at least one repetitive component, the laser pulses not irradiating the at least one particular location in the DUT continuously;
analyzing fluctuations in the laser radiation caused by the DUT to determine the behavior of the function of the DUT or of the section of the DUT, or of the component connected to the DUT, the analyzing including discretizing of the electrical representation of the fluctuations in the laser radiation, the discretizing including at least electronically measuring the electrical representation at a plurality of points within each laser pulse.

22. The method of claim 21, the acquisition electronics including at least an oscilloscope, the method further comprising:
the oscilloscope generating a trigger output; and
generating laser pulses, the laser pulses being timed based on the trigger output.

23. The method of claim 22 the laser pulses being formed by at least chopping a laser beam via an acousto-optic modulator.
